(19) United States
(12) Patent Application Publication
(10) Pub. No.: US 2026/0316037 A1
(43) Pub. Date: Oct. 15, 2026

(54) PROCESSES AND APPARATUSES FOR REDUCING ENERGY CONSUMPTION FROM A COMPRESSED AIR STREAM FOR AN OXIDATION REACTION ZONE

(71) Applicant: UOP LLC, Des Plaines, IL (US)

(72) Inventors: Brian Crawford, De Pere, WI (US); Chad A. Williams, Arlington Heights, IL (US); Ian G. Horn, Streamwood, IL (US); Kevin Tay, Northbrook, IL (US); Michael R. Van de Cotte, Palatine, IL (US); James W. Harris, Palatine, IL (US)

(21) Appl. No.: 19/632,843

(22) Filed: Mar. 30, 2026

Related U.S. Application Data
(60) Provisional application No. 63/787,346, filed on Apr. 11, 2025.

(51) Int. Cl. B01J 19/00; C07C 407/00; C07C 409/10

(52) U.S. Cl. CPC B01J 19/0013; C07C 407/00; C07C 409/10; B01J 2219/00058; B01J 2219/00103

(57) ABSTRACT

Processes and systems for reducing energy consumption from a compressed air stream for an oxidation reaction zone with: a compressor configured to receive an air stream and provide a compressed air stream; a heat exchanger configured to heat a vent gas stream from an oxidation reaction zone with the compressed air stream and provide a heated vent gas stream, the vent gas stream comprising nitrogen, oxygen, and hydrocarbons; and, an expander configured to receive the heated vent gas stream and provide a reduced pressure vent gas stream, wherein the expander and the compressor are mechanically coupled.

### CROSS-REFERENCE TO RELATED APPLICATIONS

This application which claims the benefit of U.S. Patent Application Ser. No. 63/787,346, filed on Apr. 11, 2025, the entire disclosure of which is incorporated herein by way of reference.

### FIELD OF THE INVENTION

This invention relates generally to processes and apparatuses for reducing energy consumption from a compressed air stream for an oxidation reaction zone, and more particularly to an oxidizer air compressor used in the production of phenol.

### BACKGROUND OF THE INVENTION

Phenol is an important intermediate chemical for the production of many different consumer products. One method of producing phenol is a two-stage process starting with the oxidation of cumene in the presence of air to form an intermediate peroxide, followed by the decomposition of this peroxide into phenol and acetone. In a popular process of producing phenol from cumene, the first oxidation step occurs at an intermediate pressure, requiring a compressor to compress air to the required pressure. This process also discharges a vent gas including unreacted air saturated with unreacted cumene and water. See, for example, U.S. Pat. Nos. 9,815,756 and US 11,780,795.

The compressor required to provide the air for the cumene oxidation reaction consumes a significant amount of power. The vent gas from the oxidation reaction is discharged at an elevated pressure and is typically sent to an atmospheric destination through an expansion valve. Because the vent gas has hydrocarbons and oxygen, it requires special handling to ensure that it is properly and safely disposed. Finally, cumene that is carried out with the vent gas is a valuable feed component, which should be conserved.

Accordingly, a substantial benefit can be realized to provide a process and apparatus by which energy can be recovered from the oxidation reaction vent gas to offset the power consumed by the air compressor, while at the same time ensuring that the vent gas stream is handled safely.

### SUMMARY OF THE INVENTION

The present inventors have developed processes and apparatuses for providing a compressed air stream for an oxidation reaction zone. To reduce power consumption, an expander is coupled with a compressor, via a common shaft. A heat exchanger provides heat from a stream of the compression zone to the inlet stream for the expander to reduce the chances of freezing in the expander and to increase energy recovered.

Accordingly, the present invention may therefore be characterized, in at least one aspect, as providing an apparatus for reducing energy consumption associated with a compressed air stream for an oxidation reaction zone, the apparatus having: a compressor configured to receive an air stream and provide a compressed air stream; a heat exchanger configured to heat a vent gas stream from an oxidation reaction zone and provide a heated vent gas stream; and, an expander configured to receive the heated vent gas stream and provide a reduced pressure vent gas stream.

The compressor may be a multistage compressor.

The vent gas stream may include nitrogen, oxygen, and hydrocarbons. The hydrocarbons may include cumene.

The oxidation reaction zone may be configured for a cumene oxidation reaction to cumene hydroperoxide.

The apparatus may also include a line with a valve, in which the line may be configured to provide a portion of the compressed air stream to the expander when the valve is opened.

The apparatus may also include a temperature sensor configured to provide a temperature of an input or output stream from the expander and a bypass line with a bypass valve, the bypass line configured to bypass a heat exchanger for an interstage air stream or a water control valve to or from a heat exchanger for an interstage air stream. The temperature may be used to manipulate the bypass valve or the water control valve.

The apparatus may also include an atmosphere vent line with a vent valve, in which the atmosphere vent line may be configured to vent an output stream of the expander when the vent valve is opened. The apparatus may further include a line for the output stream and a second valve, in which the line may be configured to receive the output stream and pass the output stream for further processing when the second valve is opened. The vent valve may be opened and the second valve may be closed when the output stream of the expander comprises the compressed air stream. Additionally or alternatively, the vent valve may be closed and the second valve may be opened when the output stream of the expander comprises the vent gas stream.

The expander and the compressor may be mechanically coupled.

The vent gas stream may be heated in the heat exchanger with the compressed air stream.

In a second aspect the present invention may be broadly characterized as providing a method for reducing energy consumption associated with a compressed air stream for an oxidation reaction zone by: compressing an air stream in a compressor configured to provide a compressed air stream; heating a vent gas stream from an oxidation reaction zone in a heat exchanger with the compressed air stream to provide a heated vent gas stream; and, expanding the heated vent gas stream in an expander to provide a reduced pressure vent gas stream.

The vent gas stream may include nitrogen, oxygen, and hydrocarbons. The hydrocarbons may include cumene.

The oxidation reaction zone may be configured for a cumene oxidation reaction to cumene hydroperoxide.

The compressor may be a multi-stage compressor.

The method may also include providing, via a line with a valve, a portion of the compressed air stream to the expander when the valve is opened.

The method may include monitoring a temperature of an input or output stream from the expander and, bypassing at least a portion of an interstage air stream, with a bypass line with a bypass valve, around a heat exchanger for the interstage air stream based on the temperature of the input or output stream from the expander.

The method may include venting, with an atmosphere vent line with a vent valve, an output stream of the expander when the vent valve is opened. The method may further include passing, with a line and a second valve, the output stream for further processing when the second valve is opened. When the output stream of the expander includes the compressed air stream, the vent valve may be opened and the second valve may be closed. Additionally or alternatively, when the output stream of the expander includes the vent gas stream, the vent valve may be closed and the second valve may be opened.

The expander and the compressor may be mechanically coupled.

In another aspect, the present invention may be characterized, generally, as providing a method for operating a compressor with an expander by: compressing an air stream in the compressor to provide a compressed air stream; heating a vent gas stream from an oxidation reaction zone in a heat exchanger with the compressed air stream to provide a heated vent gas stream, the vent gas stream comprising oxygen and hydrocarbons; expanding the heated vent gas stream in the expander to provide a reduced pressure vent gas stream; providing, via a line with a valve, a portion of the compressed air stream to the expander when the valve is opened; venting, with an atmosphere vent line with a vent valve, an output stream of the expander when the vent valve is opened; and, passing, with a line and a second valve, the output stream for further processing when the second valve is opened.

The method may also include, when the valve opens and a portion of the compressed air stream is provided to the expander, first opening the vent valve, and second closing the second valve.

The method may include, when the valve closes and the vent gas stream is provided to the expander, first opening the second valve, and second closing the vent valve.

The method may include monitoring a temperature of an input or output stream from the expander, and bypassing at least a portion of an interstage air stream, with a bypass line with a bypass valve, around a heat exchanger for the interstage air stream based on the temperature of the input or output stream to the expander.

The compressor may be a multi-stage compressor.

The compressor and the expander may be mechanically coupled.

The hydrocarbons may include cumene.

The oxidation reaction zone may be configured for a cumene oxidation reaction to cumene hydroperoxide.

Additional aspects, embodiments, and details of the invention, all of which may be combinable in any manner, are set forth in the following detailed description of the invention.

### DETAILED DESCRIPTION OF THE DRAWINGS

One or more exemplary embodiments of the present invention will be described below in conjunction with the following drawing figures in which like or similar elements are designated with the same reference numerals.

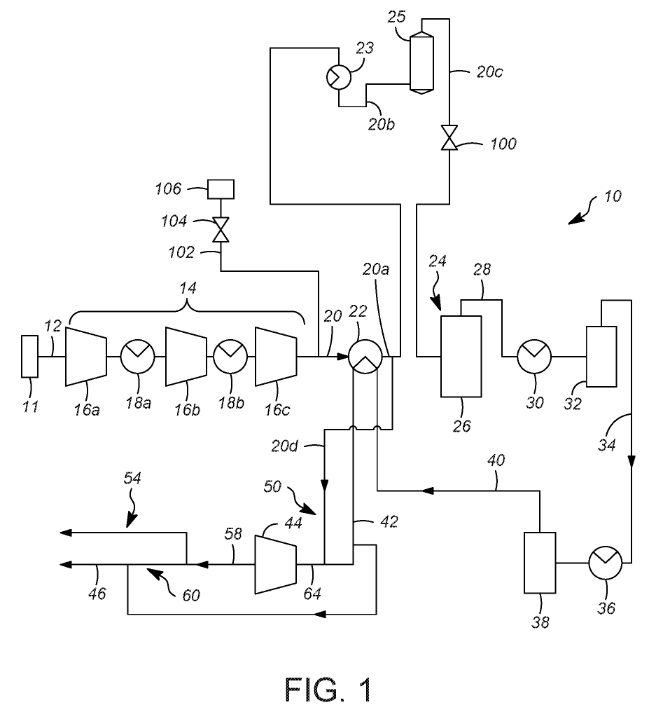

FIG. 1 shows a process flow diagram according to one or more aspects of the present invention.

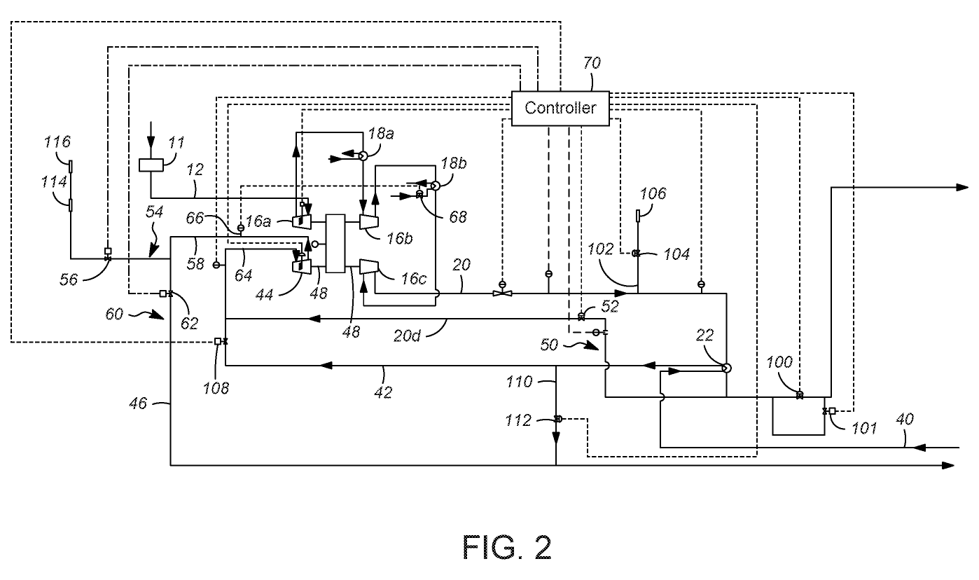

FIG. 2 shows a process flow diagram according to one or more aspects of the present invention.

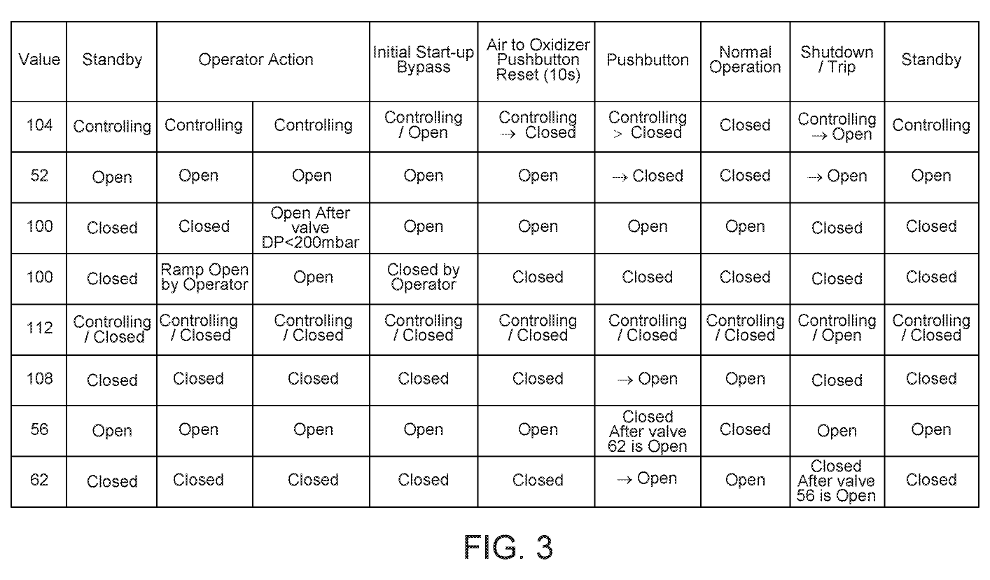

FIG. 3 is a Table showing the conditions of various valves in different stages according to one or more aspects of the present invention.

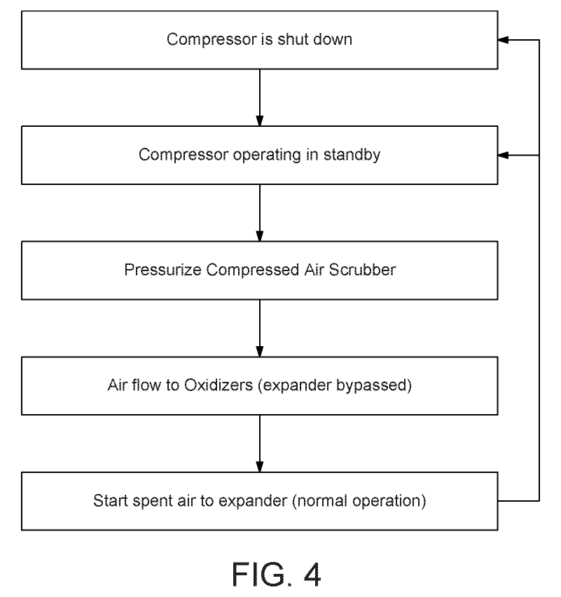

FIG. 4 is a flow chart showing steps of a startup and/or shutdown procedure according to one or more aspects of the present invention.

It should be appreciated and understood by those of ordinary skill in the art that various other components such as valves, pumps, etc. were not shown in the drawings as it is believed that the specifics of same are well within the knowledge of those of ordinary skill in the art and a description of same is not necessary for practicing or understanding the embodiments of the present invention.

### DETAILED DESCRIPTION OF THE INVENTION

As discussed above, an oxidizer air compressor system used in the production of phenol is provided which reduces power consumption of the oxidizer air compressor system, thus lowering its operating cost, and provides a mechanism to safely treat, or vent, a product stream of toxic and/or flammable compounds.

Various chemical processes, for example the phenol process, produce a vent gas stream including oxygen-depleted spent air from the reaction as a byproduct, which typically is let down across a control valve before it is sent to an incinerator. In the present invention, a turboexpander is coupled with an oxidizer air compressor. The oxidizer air compressor system additionally has a number of other design elements, including valves which, along with the turboexpander ensure safe start-up and shutdown of the coupled compressor to prevent explosive mixtures or damage to the equipment.

As described in more detail herein, vent gas with the spent air produced by the oxidation reaction will be routed through a heat exchanger, so that the effluent from the turboexpander is above the dew point of the condensables, so that there will not be any freezing concerns in the turboexpander and to increase the energy recovered. In one embodiment, the heat exchanger is a process-process exchanger, which exchanges heat with the compressor discharge. With such a system, based on computer simulations, over 25% of the power consumption of the compressor may be recovered and the overall complex power consumption of the phenol complex may be reduced by over 15%.

With these general principles in mind, the present invention will now be described in relation to the FIGURES, with the understanding that the depicted embodiment are merely exemplary or preferred.

Turning to FIG. 1, various embodiments of the present invention will be described. A system 10 or apparatus for an oxidation process utilizes a filter 11 before sending an ambient air stream 12 (having an exemplary temperature between -30 °C to 55 °C (-22 °F to 131 °F), for example, approximately 42 °C (108 °F) and exemplary pressure of approximately 101 kPa(a) (14.7 psia)) to a compressor 14. In the depicted embodiment, the compressor 14 is a multistage compressor that has three stages 16a, 16b, 16c with heat exchangers 18a, 18b provided for interstage cooling. This is merely exemplary.

From the compressor 14, a compressed air stream 20 (having an exemplary temperature of approximately 161 °C (321 °F) and exemplary pressure of approximately 590 kPa(g) (85.5 psig)) is passed to a heat exchanger 22 (discussed in more detail below) and partially cooled (for example to 88.9 °C (192 °F)). In an embodiment, a partially cooled compressed air stream 20a from the heat exchanger 22 may be further cooled in heat exchanger 23 to produce a cooled compressed air stream 20b which is then passed to an oxidation zone 24 having a reactor 26. In another embodiment, the cooled compressed air stream 20b or the partially cooled compressed air stream 20 is passed to a compressed air scrubber 25 to produce a scrubbed compressed air stream 20c which is then passed to the oxidation zone 24.

In the oxidation zone 24, oxygen from the compressed air stream 20 reacts with hydrocarbons in a known manner. In a specific embodiment, the oxygen in the compressed air stream 20 reacts with cumene at an intermediate temperature to form cumene hydroperoxide (CHP). The reaction of cumene to CHP is itself catalyzed by the presence of CHP. In order to avoid a dangerous thermal decomposition of the CHP, the temperature and pressure of the reactor 26 must be carefully controlled. In various aspects of the invention, the oxidation zone 24 may comprise multiple reactors 26 in series and/or parallel arrangement so that the oxidation reaction is properly controlled.

A gaseous effluent stream 28 comprising oxygen-depleted spent air and cumene vapor leaves the one or more reactors 26. The cumene vapor in the gaseous effluent stream 28 is a valuable feed component, which may be recovered and returned to the process. Therefore, the gaseous effluent stream 28 may be passed to a condenser 30 and then separation vessel 32 so that any condensed material may be separated from the gaseous components. In a typical embodiment, the condenser 30 is cooled with cooling water and the separation vessel 32 operates at a temperature between 25 °C and 40 °C (77 °F and 104 °F). A vapor stream 34 from the separation vessel 32 may be passed to a second condenser 36 and a second separation vessel 38 to again separate condensed materials. A vent gas stream 40 (having an exemplary temperature of approximately 5 °C (41 °F) and exemplary pressure of approximately 290 kPa(g) (42 psig)) from the second separation vessel 38 includes nitrogen, oxygen and hydrocarbons as discussed above, such a stream is usually passed to an incinerator after a pressure reduction. If the vent gas stream 40 is wet and it gets too cold during the pressure reduction, ice could form causing plugging or damaging equipment. Therefore, in order to reduce the chances of the equipment getting too cold, in the various embodiments herein, the vent gas stream 40 is passed to the heat exchanger 22 (discussed above) that also receives the compressed air stream 20. In the heat exchanger 22, the vent gas stream 40 will be heated by the compressed air stream 20, for example to a temperature of 91 °C (195 °F). This heating aids in reducing the chance that the vent gas stream 40 will freeze during a pressure reduction.

From the heat exchanger 22, a heated vent gas stream 42 is passed to an expander 44 to reduce the pressure of the heated vent gas stream 42 and provide a reduced pressure vent gas stream 46 having, for example, a pressure of 25 kPa(g) (3.6 psig). The reduced pressure vent gas stream 46 may be passed along for further processing including ultimately being passed to an incinerator.

Turning to FIG. 2, as also discussed above, in order to reduce power consumption of the compressor 14, stages 16a, 16b, 16c of the compressor 14 and the expander 44 are mechanically coupled. It is contemplated the compressor 14 and expander 44 are mechanically coupled via a common shaft 48. For example, with the compressor 14, the third stage 16c of the compressor 14 may utilize the common shaft 48 to aid in the compression. This is merely exemplary. In another contemplated embodiment, the stages 16a, 16b, 16c of the compressor 14 are all driven by a common drive gear (not shown) and the expander 44 could be coupled to the common drive gear (i.e., an integrally geared compressor).

As mentioned above, the temperature and pressure of the reactor(s) 26 in the oxidation zone 24 must be carefully monitored and controlled. In the event of an excursion, air going to the oxidizers will be stopped by closing valves 100 and 101 in the scrubbed compressed air stream 20c. This will eventually cause the vent gas stream 40 to stop.

Operating a compressor or expander with no gas flow can be very damaging to the equipment. Therefore, when scrubbed compressed air stream 20c is stopped, the compressor 14 is protected when the compressed air stream 20 is vented to atmosphere via a compressed air vent line 102, a valve 104, and a silencer 106. The expander 44 is protected when a portion 20d of the compressed air stream 20 is passed to the expander 44 through a line 50 and a valve 52.

The compressed air stream 20 comprises air and the vent gas stream 40 comprises oxygen-depleted spent air and hydrocarbons, such as, for example, cumene. Mixing these two streams together could lead to a flammable mixture, resulting in unintended combustion and potential harm to personnel and equipment. Therefore, when the portion 20d of the compressed air stream 20 is flowing to the expander 44, the heated vent gas stream 42 to the expander 44 will be stopped by closing valve 108. The heated vent gas stream 42 will be diverted to the downstream processing via line 110 and valve 112. Similarly, the reduced pressure vent gas stream 46 flowing to downstream processing is stopped by valve 62 in line 60 and the air in the expander discharge stream 58 is sent to atmosphere through the valve 56 and, for example, an absorber 114. In some configurations, a silencer 116 may also be utilized. The absorber 114, if provided, is designed to absorb any residual hydrocarbon that may be present in the expander discharge stream 58 when the portion 20d of the compressed air stream 20 is started to expander 44. In an embodiment, the absorber 114 may contain activated charcoal.

Additionally, the temperature of the expander discharge stream 58 from the expander 44 may be measured or monitored with a temperature probe or sensor 66. Based on the temperature of the expander discharge stream 58, a valve 68 associated with a water stream (such as a tempered water or a cooling water) for one or more of the interstage heat exchangers 18a, 18b may be adjusted to provide the compressed air stream 20 with the appropriate or desired temperature for heat exchanging with the vent gas stream 40 in the heat exchanger 22. In an alternative embodiment (not shown), a bypass line with a bypass control valve is placed around one or more of the interstage heat exchangers 18a, 18b. This bypass valve may be adjusted to control the temperature of the expander discharge stream 58.

Any of the foregoing valves and sensors may be in communication with a controller 70 which collects and analyzes data and sends control signals to adjust conditions, such as the opening and closing of the valves.

Turning to FIG. 3, a table depicts the status of various valves from FIGS. 1 and 2 in different operating stages of the apparatus. Furthermore, as shown in FIG. 4, a flow chart of a process according to one or more aspects of a startup or shutdown process is shown.

The systems described herein may include a controller 70 or a computing device comprising a processing or processing unit and a memory which has stored therein computer-executable instructions for implementing the processes described herein. The processing unit may comprise any suitable devices configured to cause a series of steps to be performed so as to implement the method such that instructions, when executed by the computing device or other programmable apparatus, may cause the functions/acts/steps specified in the methods described herein to be executed. The processing unit may comprise, for example, any type of general-purpose microprocessor or microcontroller, a digital signal processing (DSP) processor, a central processing unit (CPU), an integrated circuit, a field programmable gate array (FPGA), a reconfigurable processor, other suitably programmed or programmable logic circuits, or any combination.

The memory may be any suitable known or other machine-readable storage medium. The memory may comprise non-transitory computer readable storage medium such as, for example, but not limited to, an electronic, magnetic, optical, electromagnetic, infrared, or semiconductor system, apparatus, or device, or any suitable combination of the foregoing. The memory may include a suitable combination of any type of computer memory that is located either internally or externally to the device such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like. The memory may comprise any storage means (e.g., devices) suitable for retrievably storing the computer-executable instructions executable by processing unit.

Computer-executable instructions may be in many forms, including modules, executed by one or more computers or other devices. Generally, modules include routines, programs, objects, components, data structures, etc., that perform particular tasks or implement particular abstract data types. Typically, the functionality of the modules may be combined or distributed as desired in various embodiments.

It will be appreciated that the systems and devices and components thereof may utilize communication through any of various network protocols such as TCP/IP, Ethernet, FTP, HTTP and the like, and/or through various wireless communication technologies such as GSM, CDMA, Wi-Fi, and WiMAX, is and the various computing devices described herein may be configured to communicate using any of these network protocols or technologies.

Any of the above lines, conduits, units, devices, vessels, surrounding environments, zones or similar may be equipped with one or more monitoring components including sensors, measurement devices, data capture devices or data transmission devices. Signals, process or status measurements, and data from monitoring components may be utilized to monitor conditions in, around, and on process equipment. Signals, measurements, and/or data generated or recorded by monitoring components may be collected, processed, and/or transmitted through one or more networks or connections that may be private or public, general or specific, direct or indirect, wired or wireless, encrypted or not encrypted, and/or combination(s) thereof; the specification is not intended to be limiting in this respect.

Signals, measurements, and/or data generated or recorded by monitoring components may be transmitted to one or more computing devices or systems. Computing devices or systems may include at least one processor and memory storing computer-readable instructions that, when executed by the at least one processor, cause the one or more computing devices to perform a process that may include one or more steps.

For example, the one or more computing devices may be configured to receive, from one or more monitoring component, data related to at least one piece of equipment associated with the process. The one or more computing devices or systems may be configured to analyze the data. Based on analyzing the data, the one or more computing devices or systems may be configured to determine one or more recommended adjustments to one or more parameters of one or more processes described herein. The one or more computing devices or systems may be configured to transmit encrypted or unencrypted data that includes the one or more recommended adjustments to the one or more parameters of the one or more processes described herein.

### EXPERIMENTAL RESULTS

In an implementation of a configuration of the present disclosure, a compressor consumed 4955 kW of power while an expander generated 1336 kW of power. Thus, the design had a net power consumption of 3620 kW and with a power savings 27%.

### SPECIFIC EMBODIMENTS

While the following is described in conjunction with specific embodiments, it will be understood that this description is intended to illustrate and not limit the scope of the preceding description and the appended claims.

A first embodiment of the invention is an apparatus for reducing energy consumption associated with a compressed air stream for an oxidation reaction zone, the apparatus comprising a compressor configured to receive an air stream and provide a compressed air stream; a heat exchanger configured to heat a vent gas stream from an oxidation reaction zone and provide a heated vent gas stream; and, an expander configured to receive the heated vent gas stream and provide a reduced pressure vent gas stream. An embodiment of the invention is one, any or all of prior embodiments in this paragraph up through the first embodiment in this paragraph, wherein the compressor comprises a multistage compressor. An embodiment of the invention is one, any or all of prior embodiments in this paragraph up through the first embodiment in this paragraph, wherein the vent gas stream comprises nitrogen, oxygen, and hydrocarbons. An embodiment of the invention is one, any or all of prior embodiments in this paragraph up through the first embodiment in this paragraph, wherein the hydrocarbons comprise cumene. An embodiment of the invention is one, any or all of prior embodiments in this paragraph up through the first embodiment in this paragraph, wherein the oxidation reaction zone is configured for a cumene oxidation reaction to cumene hydroperoxide. An embodiment of the invention is one, any or all of prior embodiments in this paragraph up through the first embodiment in this paragraph, further comprising a line with a valve, the line configured to provide a portion of the compressed air stream to the expander when the valve is opened. An embodiment of the invention is one, any or all of prior embodiments in this paragraph up through the first embodiment in this paragraph, further comprising a temperature sensor configured to provide a temperature of an input or output stream from the expander; a bypass line with a bypass valve, the bypass line configured to bypass a heat exchanger for an interstage air stream; or a water control valve to or from a heat exchanger for an interstage air stream; in which the temperature is used to manipulate the bypass valve or the water control valve. An embodiment of the invention is one, any or all of prior embodiments in this paragraph up through the first embodiment in this paragraph, further comprising an atmosphere vent line with a vent valve, the atmosphere vent line configured to vent an output stream of the expander when the vent valve is opened. An embodiment of the invention is one, any or all of prior embodiments in this paragraph up through the first embodiment in this paragraph, further comprising a line for the output stream and a second valve, the line configured to receive the output stream and pass the output stream for further processing when the second valve is opened. An embodiment of the invention is one, any or all of prior embodiments in this paragraph up through the first embodiment in this paragraph, wherein the vent valve is opened and the second valve is closed when the output stream of the expander comprises the compressed air stream, or wherein the vent valve is closed and the second valve is opened when the output stream of the expander comprises the vent gas stream, or both. An embodiment of the invention is one, any or all of prior embodiments in this paragraph up through the first embodiment in this paragraph, wherein the expander and the compressor are mechanically coupled. An embodiment of the invention is one, any or all of prior embodiments in this paragraph up through the first embodiment in this paragraph, wherein the vent gas stream is heated in the heat exchanger with the compressed air stream.

A second embodiment of the invention is a method for reducing energy consumption associated with a compressed air stream for an oxidation reaction zone, the method comprising compressing an air stream in a compressor configured to provide a compressed air stream; heating a vent gas stream from an oxidation reaction zone in a heat exchanger with the compressed air stream to provide a heated vent gas stream; and, expanding the heated vent gas stream in an expander to provide a reduced pressure vent gas stream. An embodiment of the invention is one, any or all of prior embodiments in this paragraph up through the second embodiment in this paragraph, wherein the vent gas stream comprises nitrogen, oxygen, and hydrocarbons. An embodiment of the invention is one, any or all of prior embodiments in this paragraph up through the second embodiment in this paragraph, wherein the hydrocarbons comprise cumene. An embodiment of the invention is one, any or all of prior embodiments in this paragraph up through the second embodiment in this paragraph, wherein the oxidation reaction zone is configured for a cumene oxidation reaction to cumene hydroperoxide. An embodiment of the invention is one, any or all of prior embodiments in this paragraph up through the second embodiment in this paragraph, wherein the compressor comprises a multi-stage compressor. An embodiment of the invention is one, any or all of prior embodiments in this paragraph up through the second embodiment in this paragraph, further comprising providing, via a line with a valve, a portion of the compressed air stream to the expander when the valve is opened. An embodiment of the invention is one, any or all of prior embodiments in this paragraph up through the second embodiment in this paragraph, further comprising monitoring a temperature of an input or output stream from the expander; and, bypassing at least a portion of an interstage air stream, with a bypass line with a bypass valve, around a heat exchanger for the interstage air stream based on the temperature of the input or output stream from the expander. An embodiment of the invention is one, any or all of prior embodiments in this paragraph up through the second embodiment in this paragraph, further comprising venting, with an atmosphere vent line with a vent valve, an output stream of the expander when the vent valve is opened. An embodiment of the invention is one, any or all of prior embodiments in this paragraph up through the second embodiment in this paragraph, further comprising passing, with a line and a second valve, the output stream for further processing when the second valve is opened. An embodiment of the invention is one, any or all of prior embodiments in this paragraph up through the second embodiment in this paragraph, wherein, when the output stream of the expander comprises the compressed air stream, the vent valve is opened and the second valve is closed, or wherein, when the output stream of the expander comprises the vent gas stream, the vent valve is closed and the second valve is opened, or both. An embodiment of the invention is one, any or all of prior embodiments in this paragraph up through the second embodiment in this paragraph, wherein the expander and the compressor are mechanically coupled.

A third embodiment of the invention is a method for operating a compressor with an expander, the method comprising compressing an air stream in the compressor to provide a compressed air stream; heating a vent gas stream from an oxidation reaction zone in a heat exchanger with the compressed air stream to provide a heated vent gas stream, the vent gas stream comprising oxygen and hydrocarbons; and, expanding the heated vent gas stream in the expander to provide a reduced pressure vent gas stream; providing, via a line with a valve, a portion of the compressed air stream to the expander when the valve is opened; venting, with an atmosphere vent line with a vent valve, an output stream of the expander when the vent valve is opened; and, passing, with a line and a second valve, the output stream for further processing when the second valve is opened. An embodiment of the invention is one, any or all of prior embodiments in this paragraph up through the third embodiment in this paragraph, further comprising when the valve opens and a portion of the compressed air stream is provided to the expander, first opening the vent valve, and second closing the second valve. An embodiment of the invention is one, any or all of prior embodiments in this paragraph up through the third embodiment in this paragraph, further comprising when the valve closes and the vent gas stream is provided to the expander, first opening the second valve, and second closing the vent valve. An embodiment of the invention is one, any or all of prior embodiments in this paragraph up through the third embodiment in this paragraph, further comprising monitoring a temperature of an input or output stream from the expander; and, bypassing at least a portion of an interstage air stream, with a bypass line with a bypass valve, around a heat exchanger for the interstage air stream based on the temperature of the input or output stream to the expander. An embodiment of the invention is one, any or all of prior embodiments in this paragraph up through the third embodiment in this paragraph, wherein the compressor comprises a multi-stage compressor. An embodiment of the invention is one, any or all of prior embodiments in this paragraph up through the third embodiment in this paragraph, wherein the compressor and the expander are mechanically coupled. An embodiment of the invention is one, any or all of prior embodiments in this paragraph up through the third embodiment in this paragraph, wherein the hydrocarbons comprise cumene. An embodiment of the invention is one, any or all of prior embodiments in this paragraph up through the third embodiment in this paragraph, wherein the oxidation reaction zone is configured for a cumene oxidation reaction to cumene hydroperoxide.

Without further elaboration, it is believed that using the preceding description that one skilled in the art can utilize the present invention to its fullest extent and easily ascertain the essential characteristics of this invention, without departing from the spirit and scope thereof, to make various changes and modifications of the invention and to adapt it to various usages and conditions. The preceding preferred specific embodiments are, therefore, to be construed as merely illustrative, and not limiting the remainder of the disclosure in any way whatsoever, and that it is intended to cover various modifications and equivalent arrangements included within the scope of the appended claims.

In the foregoing, all temperatures are set forth in degrees Celsius and, all parts and percentages are by weight, unless otherwise indicated.

What is claimed is:

1. An apparatus for reducing energy consumption associated with a compressed air stream for an oxidation reaction zone, the apparatus comprising:
a compressor configured to receive an air stream and provide a compressed air stream;
a heat exchanger configured to heat a vent gas stream from an oxidation reaction zone and provide a heated vent gas stream; and,
an expander configured to receive the heated vent gas stream and provide a reduced pressure vent gas stream.

2. The apparatus of claim 1, wherein the compressor comprises a multistage compressor, or
wherein the vent gas stream comprises nitrogen, oxygen, and hydrocarbons, or
wherein the hydrocarbons comprise cumene, or
wherein the oxidation reaction zone is configured for a cumene oxidation reaction to cumene hydroperoxide, or
any combination thereof.

3. The apparatus of claim 1, further comprising:
a line with a valve, the line configured to provide a portion of the compressed air stream to the expander when the valve is opened.

4. The apparatus of claim 1, further comprising:
a temperature sensor configured to provide a temperature of an input or output stream from the expander;
a bypass line with a bypass valve, the bypass line configured to bypass a heat exchanger for an interstage air stream; or
a water control valve to or from a heat exchanger for an interstage air stream;
wherein said temperature is used to manipulate the bypass valve or the water control valve.

5. The apparatus of claim 1, further comprising:
an atmosphere vent line with a vent valve, the atmosphere vent line configured to vent an output stream of the expander when the vent valve is opened.

6. The apparatus of claim 5, further comprising:
a line for the output stream and a second valve, the line configured to receive the output stream and pass the output stream for further processing when the second valve is opened.

7. The apparatus of claim 6, wherein the vent valve is opened and the second valve is closed when the output stream of the expander comprises the compressed air stream, or
wherein the vent valve is closed and the second valve is opened when the output stream of the expander comprises the vent gas stream, or
7both.

8. The apparatus of claim 1, wherein the expander and the compressor are mechanically coupled, or
wherein the vent gas stream is heated in the heat exchanger with the compressed air stream, or
8both.

9. A method for reducing energy consumption associated with a compressed air stream for an oxidation reaction zone, the method comprising:
compressing an air stream in a compressor configured to provide a compressed air stream;
heating a vent gas stream from an oxidation reaction zone in a heat exchanger with the compressed air stream to provide a heated vent gas stream; and,
expanding the heated vent gas stream in an expander to provide a reduced pressure vent gas stream.

10. The method of claim 9, wherein the vent gas stream comprises nitrogen, oxygen, and hydrocarbons, or
wherein the hydrocarbons comprise cumene, or
wherein the oxidation reaction zone is configured for a cumene oxidation reaction to cumene hydroperoxide, or
wherein the compressor comprises a multi-stage compressor, or
any combination thereof.

11. The method of claim 9, further comprising:
providing, via a line with a valve, a portion of the compressed air stream to the expander when the valve is opened.

12. The method of claim 9, further comprising:
monitoring a temperature of an output or an input stream from the expander; and,
bypassing at least a portion of an interstage air stream, with a bypass line with a bypass valve, around a heat exchanger for the interstage air stream based on the temperature of the output or input stream from the expander.

13. The method of claim 9, further comprising:
venting, with an atmosphere vent line with a vent valve, an output stream of the expander when the vent valve is opened.

14. The method of claim 13, further comprising:
passing, with a line and a second valve, the output stream for further processing when the second valve is opened.

15. The method of claim 14, wherein, when the output stream of the expander comprises the compressed air stream, the vent valve is opened and the second valve is closed, or
wherein, when the output stream of the expander comprises the vent gas stream, the vent valve is closed and the second valve is opened, or
15both.

16. The method of claim 9, wherein the expander and the compressor are mechanically coupled.

17. A method for operating a compressor with an expander, the method comprising:
compressing an air stream in the compressor to provide a compressed air stream;
heating a vent gas stream from an oxidation reaction zone in a heat exchanger with the compressed air stream to provide a heated vent gas stream, the vent gas stream comprising oxygen and hydrocarbons; and,
expanding the heated vent gas stream in the expander to provide a reduced pressure vent gas stream;
providing, via a line with a valve, a portion of the compressed air stream to the expander when the valve is opened;
venting, with an atmosphere vent line with a vent valve, an output stream of the expander when the vent valve is opened; and,
passing, with a line and a second valve, the output stream for further processing when the second valve is opened.

18. The method of claim 17, further comprising:
when the valve opens and a portion of the compressed air stream is provided to the expander, first opening the vent valve, and second closing the second valve; or
when the valve closes and the vent gas stream is provided to the expander, first opening the second valve, and second closing the vent valve; or
18both.

19. The method of claim 17, further comprising:
monitoring a temperature of an input or output stream from the expander; and,
bypassing at least a portion of an interstage air stream, with a bypass line with a bypass valve, around a heat exchanger for the interstage air stream based on the temperature of the input or output stream to the expander.

20. The method of claim 17, wherein the compressor comprises a multi-stage compressor, or
wherein the compressor and the expander are mechanically coupled, or
wherein the hydrocarbons comprise cumene, or
wherein the oxidation reaction zone is configured for a cumene oxidation reaction to cumene hydroperoxide, or
any combination thereof.
